(19) United States
(12) Patent Application Publication
(10) Pub. No.: US 2024/0114761 A1
(43) Pub. Date: Apr. 4, 2024

(54) DISPLAY PANEL AND REPAIRING METHOD THEREOF

(71) Applicant: Shenzhen China Star Optoelectronics Semiconductor Display Technology Co., Ltd., Shenzhen, Guangdong (CN)

(72) Inventor: Song YUAN, Shenzhen, Guangdong (CN)

(21) Appl. No.: 17/764,671

(22) PCT Filed: Mar. 16, 2022
(86) PCT No.: PCT/CN2022/081184

§ 371 Date: Aug. 31, 2023

(30) Foreign Application Priority Data
Feb. 28, 2022 (CN) 202210185032.8

(51) Int. Cl. H10K 71/00; H10K 59/126; H10K 59/131; H10K 59/80

(52) U.S. Cl. CPC H10K 71/861; H10K 59/126; H10K 59/131; H10K 59/80516

(57) ABSTRACT

Embodiments of the present application disclose a display panel and a repairing method of a display panel. The display panel includes an array substrate, wherein the array substrate includes a power signal trace and at least one auxiliary trace; a plurality of light-emitting devices, wherein each of light-emitting devices includes a first electrode and a second electrode; and a plurality of auxiliary electrodes disposed in a same layer as the first electrode, wherein the auxiliary electrode is electrically connected to the auxiliary trace. When there are bright spots, the first electrode and the auxiliary electrode corresponding to the bright spots are melted by a laser irradiation, so that the first electrode and the auxiliary electrode are connected to eliminate an abnormality due to the bright spots.

### TECHNICAL FIELD

The present application relates to a display field, in particular to a display panel and a repairing method of the display panel.

### BACKGROUND

Organic light-emitting display (OLED) panels have been widely used in people's life, for example, used in display screens of mobile phones, computers, and the like. In a production and manufacture of the organic light-emitting display panels, bright spots on a display panel are present for various reasons, for example, a short circuit due to the presence of particles, a short circuit due to trace or electrode etching residue, an anode short circuit, and an abnormality due to an insulating layer opening in a production process of the display panel. The bright spots on the display panel not only reduce a yield of the display panel, but also reduce a display quality.

Therefore, there is a need to provide a display panel or a repairing method of the display panel in order to improve or eliminate a problem of abnormalities due to the bright spots in the display panel, and to improve the yield and the display quality of the display panel.

### Technical Problems

Embodiments of the present application provide a display panel and a repairing method of the display panel, which can improve or eliminate a problem of abnormalities due to bright spots in the display panel, and a problem of a decrease in a yield and a display quality of the display panel caused by the abnormalities due to bright spots.

### SUMMARY

An embodiment of the present application provides a display panel, comprising:
an array substrate, wherein the array substrate includes a power signal trace and at least one auxiliary trace; and
a plurality of light-emitting devices disposed on the array substrate in an array, wherein each of the light-emitting devices includes a first electrode and a second electrode, and the second electrode is disposed on a side of the first electrode away from the array substrate;
wherein the display panel further includes a plurality of auxiliary electrodes disposed in the same layer as the first electrode, each of the auxiliary electrodes is disposed corresponding to the first electrode of at least one of the light-emitting devices, the auxiliary electrode is electrically connected to the auxiliary trace, and a potential of the auxiliary trace is less than a potential of the power signal trace.

Optionally, in some embodiments of the present application, a distance between the auxiliary electrode and the first electrode corresponding to the auxiliary electrode is less than or equal to 2 μm.

Optionally, in some embodiments of the present application, each of the auxiliary electrodes is disposed corresponding to the first electrodes of the plurality of light-emitting devices.

Optionally, in some embodiments of the present application, the plurality of light-emitting devices include red light-emitting devices, green light-emitting devices, and blue light-emitting devices, and each of the auxiliary electrodes is disposed corresponding to the first electrode of at least one of the red light-emitting devices, the first electrode of at least one of the green light-emitting devices, and the first electrode of at least one of the blue light-emitting devices.

Optionally, in some embodiments of the present application, the first electrode of at least one of the light-emitting devices is connected to the auxiliary electrode corresponding to first electrode.

Optionally, in some embodiments of the present application, the array substrate further includes a thin film transistor, and a first metal layer disposed between the thin film transistor and the light-emitting device, wherein the auxiliary trace is disposed in a same layer as the first metal layer.

Optionally, in some embodiments of the present application, the array substrate further includes a thin film transistor, and a first metal layer disposed between the thin film transistor and the light-emitting device, wherein the auxiliary trace is disposed in a same layer as the first metal layer.

Optionally, in some embodiments of the present application, wherein the array substrate further includes a thin film transistor, and a first metal layer disposed between the thin film transistor and the light-emitting device, wherein the auxiliary trace is disposed in a same layer as the first metal layer.

Optionally, in some embodiments of the present application, wherein the array substrate further includes a thin film transistor, and a first metal layer disposed between the thin film transistor and the light-emitting device, wherein the auxiliary trace is disposed in a same layer as the first metal layer.

Optionally, in some embodiments of the present application, the first electrode is connected to a drain of the thin film transistor through the first metal layer.

Optionally, in some embodiments of the present application, the array substrate further includes a thin film transistor, the thin film transistor includes a gate electrode, an active layer, and a source/drain electrode, and the auxiliary trace is disposed in a same layer as the gate electrode or the source/drain electrode.

Optionally, in some embodiments of the present application, the array substrate further includes a thin film transistor, the thin film transistor includes a gate electrode, an active layer, and a source/drain electrode, and the auxiliary trace is disposed in a same layer as the gate electrode or the source/drain electrode.

Optionally, in some embodiments of the present application, the array substrate further includes a thin film transistor, the thin film transistor includes a gate electrode, an active layer, and a source/drain electrode, and the auxiliary trace is disposed in a same layer as the gate electrode or the source/drain electrode.

Optionally, in some embodiments of the present application, the array substrate further includes a thin film transistor, the thin film transistor includes a gate electrode, an active layer, and a source/drain electrode, and the auxiliary trace is disposed in a same layer as the gate electrode or the source/drain electrode.

Optionally, in some embodiments of the present application, the array substrate further includes a second metal layer, a thin film transistor disposed on the second metal layer, wherein the auxiliary trace is disposed in a same layer as the second metal layer.

Optionally, in some embodiments of the present application, wherein the array substrate further includes a second metal layer, a thin film transistor disposed on the second metal layer, wherein the auxiliary trace is disposed in a same layer as the second metal layer.

Optionally, in some embodiments of the present application, wherein the array substrate further includes a second metal layer, a thin film transistor disposed on the second metal layer, wherein the auxiliary trace is disposed in a same layer as the second metal layer.

Accordingly, an embodiment of the present application further provides a repairing method of a display panel. In the display panel described in any one of the above, the repairing method of the display panel includes:

S100, irradiating the auxiliary electrode and the first electrode corresponding to the auxiliary electrode by a laser, to melt the auxiliary electrode and the first electrode to electrically connect to each other; and

S200, supplying a potential to the auxiliary trace, and supplying an electric signal by the auxiliary trace to the first electrode connected to the auxiliary electrode.

Optionally, in some embodiments of the present application, a distance between the auxiliary electrode and the first electrode corresponding to the auxiliary electrode is less than or equal to 2 μm.

Optionally, in some embodiments of the present application, each of the auxiliary electrodes is disposed corresponding to the first electrodes of the plurality of light-emitting devices.

### Beneficial Effects

Embodiments of the present application provide a display panel and a repairing method of a display panel. The display panel includes an array substrate, wherein the array substrate includes a power signal trace and at least one auxiliary trace; a plurality of light-emitting devices disposed on the array substrate in an array, wherein each of the light-emitting devices includes a first electrode and a second electrode, and the second electrode is disposed on a side of the first electrode away from the array substrate; wherein the display panel further includes a plurality of auxiliary electrodes disposed in a same layer as the first electrode, each of the auxiliary electrodes is disposed corresponding to the first electrode of at least one of the light-emitting devices, the auxiliary electrode is electrically connected to the auxiliary trace, and a potential of the auxiliary trace is less than a potential of the power signal trace. When there is a bright spot, the first electrode and the auxiliary electrode corresponding to the bright spot are melted by a laser irradiation, and a low potential is supplied to the auxiliary trace to eliminate a larger voltage difference between the first electrode and the second electrode, thereby changing the bright spot into a dark spot. Therefore, an abnormality due to the bright spots in the display panel can be improved or eliminated, and the yield and the display quality of the display panel can be improved.

### BRIEF DESCRIPTION OF THE DRAWINGS

In order to more clearly illustrate the technical solutions in the embodiments of the present application, the accompanying drawings required for use in the description of the embodiments will be briefly described below. It will be apparent that the accompanying drawings in the following description are merely some embodiments of the present application, and other drawings may be obtained from these drawings without creative effort by those skilled in the art.

FIG. 1 is a first schematic partial top view of an auxiliary electrode of a display panel according to an embodiment of the present application;

FIG. 2 is a second schematic partial top view of an auxiliary electrode of a display panel according to an embodiment of the present application;

FIG. 3 is a first schematic cross-sectional view of a display panel according to an embodiment of the present application;

FIG. 4 is a second schematic cross-sectional view of a display panel according to an embodiment of the present application;

FIG. 5 is a third schematic cross-sectional view of a display panel according to an embodiment of the present application;

FIG. 6 is a fourth schematic cross-sectional view of a display panel according to an embodiment of the present application;

FIG. 7 is a schematic diagram of a circuit principle of a repairing method of a display panel according to an embodiment of the present application;

FIG. 8 is a schematic diagram of a repair process of a repairing method of a display panel according to an embodiment of the present application;

FIG. 9 is a first schematic cross-sectional view of a display panel after repairing according to an embodiment of the present application;

FIG. 10 is a second schematic cross-sectional view of a display panel after repairing according to an embodiment of the present application;

FIG. 11 is a flowchart of a repairing method of a display panel according to an embodiment of the present application.

### DETAILED DESCRIPTION OF THE EMBODIMENTS

The following describes the technical solutions of the embodiments of the present application in a clear and complete manner with reference to the accompanying drawings for the embodiments of the present application. It will be apparent that the described embodiments are only some of the embodiments of the present application, but not all of the embodiments. Based on the embodiments of the present application, other embodiments obtained by those skilled in the art without creative effort fall within the scope of the present application. Furthermore, it should be understood that the specific embodiments described herein are intended only to illustrate and explain the present application and are not intended to limit the present application. The terms “upper” and “lower” used in the present application in the absence of a reverse description, generally refer the upper and lower parts of the device in actual use or operation, in particular in the drawing direction; and the terms “in” and “outside” are for the profile of the device.

An embodiment of the present application provides a display panel comprising an array substrate and a plurality of light-emitting devices disposed on an array substrate, wherein the array substrate includes a power signal trace and at least one auxiliary trace, each of light-emitting devices includes a first electrode, and a second electrode, and the second electrode is disposed on a side of the first electrode away from the array substrate. A light-emitting device layer further includes a plurality of auxiliary electrodes disposed in a same layer as the first electrode, and each of the auxiliary electrodes is disposed corresponding to the first electrode of at least one of the light-emitting devices. The auxiliary electrode is electrically connected to the auxiliary trace, and a potential of the auxiliary trace is less than a potential of the power signal trace.

Embodiments of the present application provide a display panel and a repairing method of the display panel. Detailed description will be followed. It should be noted that an order of description of the following embodiments is not a limitation on a preferred order of the embodiments.

### Embodiment 1

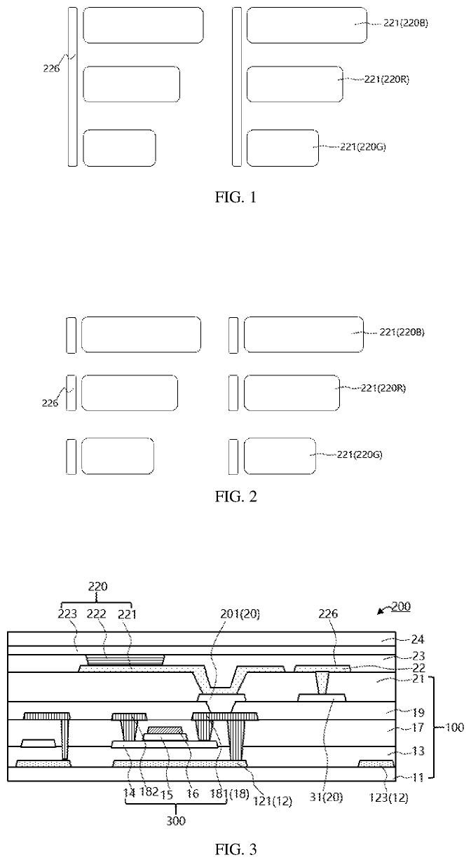

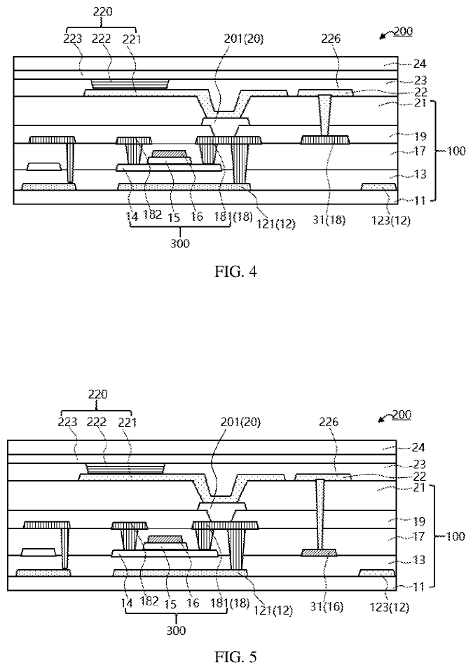

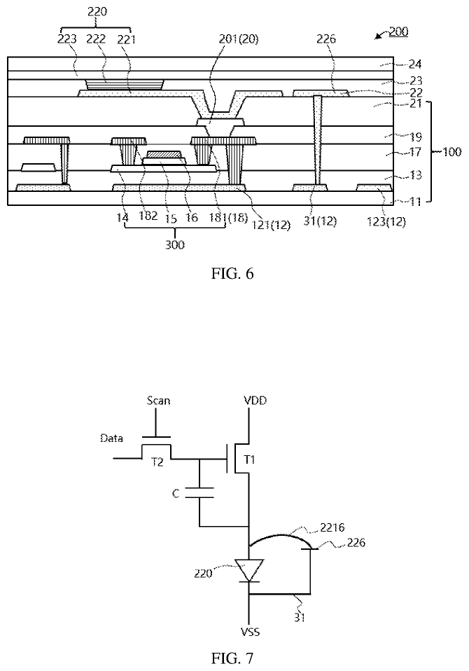

References are made to FIGS. 1, 2, 3, 4 and 5, wherein FIG. 1 is a first schematic top view of an auxiliary electrode of a display panel 200 according to an embodiment of the present application. FIG. 2 is a second schematic top view of an auxiliary electrode of a display panel 200 according to an embodiment of the present application; FIG. 3 is a first schematic cross-sectional view of a display panel 200 according to an embodiment of the present application; FIG. 4 is a second schematic cross-sectional view of a display panel 200 according to an embodiment of the present application; FIG. 5 is a third schematic cross-sectional view of a display panel 200 according to an embodiment of the present application; and FIG. 6 is a fourth schematic cross-sectional view of a display panel 200 according to an embodiment of the present application.

An embodiment of the present application provides a display panel 200 comprising an array substrate 100 and a plurality of light-emitting devices 220, wherein the array substrate 100 includes a power signal trace 123 and at least one auxiliary trace 31, the plurality of light-emitting devices 220 are disposed on the array substrate 100, each of the light-emitting devices 220 includes a first electrode 221 and a second electrode 223, and the second electrode 223 is disposed on a side of the first electrode 221 away from the array substrate 100. The display panel 200 further includes a plurality of auxiliary electrodes 226 disposed on a same layer as the first electrodes 221. Each of the auxiliary electrodes 226 is disposed corresponding to the first electrode 221 of at least one of the light-emitting devices 220, the auxiliary electrode 226 is electrically connected to the auxiliary trace 31, and a potential of the auxiliary trace 31 is less than a potential of the power signal trace 123.

Specifically, the plurality of light-emitting devices 220 may include, but are not limited to, red light-emitting devices 220R, green light-emitting devices 220G, and blue light-emitting devices 220B.

Specifically, the light-emitting device 220 includes the first electrode 221 and the second electrode 223, wherein the second electrode 223 is disposed on the side of the first electrode 221 away from the array substrate 100, and the light-emitting device 220 further includes a light-emitting material layer 222.

Specifically, the first electrode 221 may be an anode, and the second electrode 223 may be a cathode, but is not limited thereto. For example, the first electrode 221 may be a cathode, and the second electrode 223 may be an anode.

Specifically, the display panel 200 further includes the plurality of auxiliary electrodes 226 provided in the same layer as the first electrode 221, and the auxiliary electrode 226 may be made of the same material as the first electrode 221 by the same process as that of the first electrode 221. For example, when patterning a first electrode metal layer 22 to form the first electrode 221, the first electrode 221 and the auxiliary electrode 226 are formed at a same time by patterning.

Specifically, the auxiliary electrode 226 is disposed corresponding to the first electrode 221 of at least one of the light-emitting devices 220, that is, the auxiliary electrode 226 is disposed adjacent to the first electrode 221 of at least one of the light-emitting devices 220.

In the embodiment, the display panel 200 is provided, and the array substrate 100 includes at least one auxiliary trace 31. The display panel 200 further includes the plurality of auxiliary electrodes 226 disposed on the same layer as the first electrode 221, Each of the auxiliary electrodes 226 is disposed adjacent to the first electrode 221 of at least one of the light-emitting devices 220, and the auxiliary electrode 226 is electrically connected to the auxiliary trace 31. When there is a bright spot on the display panel 200, the first electrode 221 or/and the auxiliary electrode 226 corresponding to the bright spot are irradiated with a laser, the first electrode 221 and the auxiliary electrode 226 are connected to each other after melting, and a low-potential signal is sent to the auxiliary trace 31 to eliminate a large voltage difference between the first electrode 221 and the second electrode 223. The bright spots are changed to dark spots, an abnormality due to the bright spots in the display panel 200 can be improved or eliminated, and a yield and a display quality of the display panel can be improved.

In some embodiments, a distance between the auxiliary electrode 226 and the first electrode 221 corresponding and adjacent to the auxiliary electrode 226 is less than or equal to 2 μm.

Specifically, the distance between the auxiliary electrode 226 and the first electrode 221 corresponding and adjacent to the auxiliary electrode 226 is short, and when there are bright spots on the display panel 200, the first electrode 221 and/or the auxiliary electrode 226 corresponding to the bright spots are irradiated with the laser, and the first electrode 221 and the auxiliary electrode 226 are more easily connected to each other after melting, thereby eliminating the bright spots.

Further, the distance between the auxiliary electrode 226 and the first electrode 221 corresponding and adjacent to the auxiliary electrode 226 is less than or equal to 1 μm, and the bright spots may be better repaired.

In some embodiments, the array substrate 100 further includes a power signal trace 123, and the potential of the auxiliary trace 31 is less than the potential of the power signal trace 123.

Specifically, the power supply signal trace 123 is a signal trace VDD of the pixel driving circuit, and the signal trace VDD is connected to the first electrode 221 of the light-emitting device 220 by a driving transistor T1. The potential of the auxiliary trace 226 is less than the potential of the power signal trace 123, this is, the auxiliary electrode 226 is a low potential. The potential of the auxiliary trace 226 is less than the potential of the power signal trace 123. When there are bright spots in the display panel 220, repairing the display panel. After repairing, the first electrode 221 is connected to the auxiliary electrode 226, the potential of the auxiliary trace 31 is supplied to a repaired first electrode 221, and a large voltage difference between the repaired first electrode 221 and the second electrode 223 is reduced and eliminated. The light-emitting device 220 with bright spots before repairing does not emit light or the luminous brightness is very low, and the light-emitting device 220 with bright spots after repairing can be changed to dark spots. Thus, the bright spots are changed into the dark spots.

Further, the potential of the auxiliary trace 31 is the same as the potential of the second electrode power supply signal trace, so that the potential of the repaired first electrode 221 is the same as the potential of the second electrode, thereby eliminating the bright spots.

Further, the second electrode is a cathode, and the second electrode power signal trace is a cathode signal trace VSS. The signal trace VDD and the cathode signal trace VSS of the pixel driving circuit are not described herein again.

In some embodiments, each of the auxiliary electrodes 226 is disposed corresponding to more than one of the first electrodes 221 of the plurality of light-emitting devices 220.

Specifically, as shown in FIG. 1, each of the auxiliary electrodes 226 is disposed adjacent to more than one of the first electrodes 221 of the plurality of light-emitting devices 220, so that the number of the auxiliary electrodes 226 is reduced, the number of connection portions and connection holes between the auxiliary electrodes 226 and the auxiliary traces 31 is reduced, and a space utilization ratio of the display panel 200 is improved, thereby sparing more spaces in the display panel 200 to dispose other structure.

Specifically, as shown in FIG. 2, one auxiliary electrode 226 may be disposed adjacent to one first electrode 221 of the light-emitting device 220.

In some embodiments, the plurality of light-emitting devices 220 include red light-emitting devices 220R, green light-emitting devices 220G, blue light-emitting devices 220B, and each of the auxiliary electrodes 226 is disposed corresponding to the first electrode 221 of at least one of the red light-emitting devices 220R, the first electrode 221 of at least one of the green light-emitting devices 220G, and the first electrode 221 of at least one of the blue light-emitting devices 220B.

As shown in FIG. 2, the auxiliary electrode 226 is disposed adjacent to the first electrode 221 of at least one of the red light-emitting devices 220R, the first electrode 221 of at least one of the green light-emitting devices 220G, and the first electrode 221 of at least one of the blue light-emitting devices 220B. When bright spots occur, the red light-emitting device 220R, the green light-emitting device 220G, and the blue light-emitting device 220B in one pixel may be connected to a same auxiliary electrode 226, and the bright spots of the red light-emitting device 220R, the green light-emitting device 220 G, and the blue light-emitting device 220B in one pixel may be simultaneously changed into dark spots, so that a color difference may be eliminated by a change of a single light-emitting device 220 into dark spots.

In some embodiments, the first electrode 221 of at least one of the light-emitting devices 220 is connected to the auxiliary electrode 226 corresponding to the first electrode 221.

Specifically, when the display panel 200 has bright spots, after the display panel 200 is repaired, the first electrode 221 of the at least one of the light-emitting device 220s is connected to the auxiliary electrode 226 corresponding to the first electrode 221 in the display panel 200, which indicates that the bright spots of the display panel 200 have been repaired. The yield and the display quality of the display panel 200 are improved.

### Example 2

This embodiment is the same as or similar to the above embodiment except that a position of an auxiliary trace 31 is further described.

In some embodiments, the array substrate 100 further includes a thin film transistor 300, a first metal layer 20 between the thin film transistor 300 and the light-emitting device 220; and an auxiliary trace 31 is disposed in a same layer as the first metal layer 20.

Specifically, as shown in FIG. 3, the array substrate 100 includes a substrate 11, the thin film transistor 300 disposed on the substrate 11, and the first metal layer 20 disposed on the thin film transistor 300; and the auxiliary trace 31 is disposed in the same layer as the first metal layer 20.

Specifically, the auxiliary trace 31 is made of a same material as the first metal layer 20, and may be manufactured in a same process as the first metal layer 20.

In some embodiments, the first electrode 221 is connected to a drain of the thin film transistor 300 by the first metal layer 20.

Specifically, the first metal layer 20 includes a connection electrode 201, wherein the connection electrode 201 is connected between the first electrode 221 and the drain of the thin film transistor 300, or the connection electrode 201 is connected between the first electrode 221 and a source of the thin film transistor 300. In the embodiment, the source and the drain may be interchangeable as long as they are configured as two ends of the thin film transistor.

In some embodiments, the array substrate 100 further includes the thin film transistor 300, wherein the thin film transistor 300 includes a gate electrode 16, an active layer 14, and a source/drain electrode 18. The auxiliary trace 31 is disposed on a same layer as the gate electrode 16 and the source/drain electrode 18.

Specifically, as shown in FIGS. 4 and 5, the auxiliary trace 31 is disposed in the same layer as the gate electrode 16 or the source/drain electrode 18, thereby simplifying a manufacture process of the array substrate 100.

Specifically, the auxiliary trace 31 may be made of a same material as the gate electrode 16 or the source/drain electrode 18, and may be made of the same process as the gate electrode 16 or the source/drain electrode 18.

In some embodiments, the array substrate 100 also includes a second metal layer 12, and the thin film transistor 300 disposed on the second metal layer 12, and the auxiliary trace 31 disposed in a same layer as the second metal layer 12.

Specifically, as shown in FIG. 6, the second metal layer 12 is further disposed between the substrate 11 and the thin film transistor 300, and the auxiliary trace 31 and the second metal layer are disposed on a same layer to simplify the manufacture process of the array substrate 100.

Specifically, the auxiliary trace 31 is made of a same material as the second metal layer 12, and may be manufactured in a same process as the second metal layer 12.

Specifically, the second metal layer 12 may be patterned to form a light shielding electrode 121 (LS), a power signal trace 123, and a cathode signal trace VSS, and structures as the like. Details are not described herein.

Specifically, as an example shown in FIG. 3, the array substrate 100 includes a substrate 11, a second metal layer 12, a first insulating layer 13, a semiconductor layer 14, a gate insulating layer 15, a gate electrode 16, an interlayer insulating layer 17, a source/drain layer 18, a second insulating layer 19, a first metal layer 20, and a planarization layer 21 which are sequentially disposed.

Specifically, as exemplified in FIG. 3, the display panel 200 further includes a first electrode metal layer 22 disposed on the planarization layer 21 of the array substrate 100, a pixel definition layer 23 disposed on the first electrode metal layer 22, and an encapsulation layer 24 disposed on the light-emitting device 220. The first electrode metal layer 22 includes a first electrode 221 and an auxiliary electrode 226. Specifically, as exemplified in FIGS. 3 and 6, the array substrate 100 includes a thin film transistor 300, wherein each thin film transistor 300 includes a semiconductor layer 14, a gate electrode 16, a gate insulating layer 15 between the semiconductor layer 14 and the gate electrode 16, a source electrode 182 and a drain electrode 181 formed by metal patterning a source/drain electrode 18.

It should be noted that the source electrode 182 and the drain electrode 181 may be interchangeable.

It should be noted that although FIG. 3 illustrates a layer structure of the array substrate 100 as an example, the layer structure of the array substrate 100 is not limited thereto. For example, the power signal trace 123 and the cathode signal trace VSS may not be formed of the second metal layer 12, but may be formed of other metal layers. For example, the thin film transistor 300 of the array substrate 100 may be a top gate structure or a bottom gate structure.

It should be noted that a material of each layer of the array substrate 100 and a material of each structure of the thin film transistor 300 may be any of the materials used in the prior art, and details are not described herein.

It should be noted that the display panel 200 may further include a pixel definition layer 23 and an encapsulation layer 24 disposed on the second electrode 223, and details are not described herein.

In this embodiment, a film position of the auxiliary trace 31 is further described, and the manufacture process of the array substrate 100 may be simplified.

### Example 3

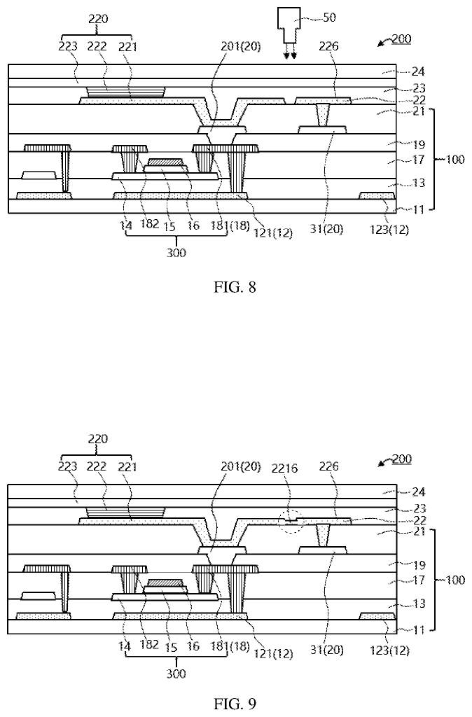

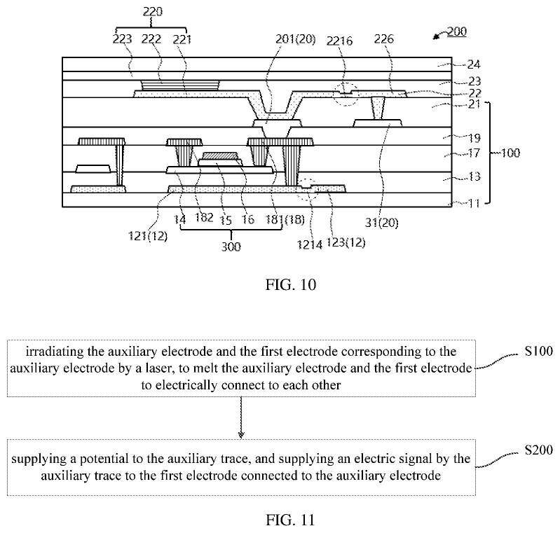

References are made to FIGS. 7, 8, 9, 10 and 11, wherein FIG. 7 is a schematic diagram of a circuit principle of a repairing method of a display panel 200 according to an embodiment of the present application; FIG. 8 is a schematic diagram of a process of repairing a display panel 200 according to an embodiment of the present application; FIG. 9 is a first schematic cross-sectional view of a display panel 200 after repairing according to an embodiment of the present application; FIG. 10 is a second schematic cross-sectional view of a display panel 200 after repairing according to an embodiment of the present application; FIG. 11 is a flowchart of a repairing method of a display panel 200 according to an embodiment of the present application.

The embodiment provides a repairing method for a display panel. In any one of the display panels 200 in the above embodiments, the display panel 200 is repaired by step S100 or/and step S200.

Step S100: irradiating an auxiliary electrode and a first electrode corresponding to the auxiliary electrode by a laser, to melt the auxiliary electrode and the first electrode to electrically connect to each other.

Specifically, as shown in FIG. 8, the auxiliary electrode 226 and the first electrode 221 corresponding thereto are irradiated by the laser 50 to melt, so that auxiliary electrode 226 and the first electrode 221 are connected electrically to each other.

Specifically, the auxiliary electrode 226 and/or the first electrode 221 are melted to form an auxiliary connection electrode 2216 (as shown in a spotted circle in FIG. 9), and the auxiliary connection electrode 2216 connects the auxiliary electrode 226 with the first electrode 221 corresponding to the auxiliary electrode 226.

In step S200, supplying a potential to an auxiliary trace, and supplying an electric signal by the auxiliary trace to the first electrode connected to the auxiliary electrode.

Specifically, the potential is supplied to the auxiliary trace 226, and the auxiliary trace 31 supplies the electric signal to the first electrode 221 connected to the auxiliary electrode 226.

Specifically, the potential of the auxiliary trace 31 has been described in the above-described embodiments and will not be described herein again.

Specifically, as shown in FIG. 9, after the display panel is repaired, at least one of the first electrode 221 of at least one of the light-emitting devices 220 is connected to the auxiliary electrode 226 corresponding to the first electrode 221.

Specifically, when the display panel 200 has bright spots, after the display panel 200 is repaired, in the display panel 200 there is a case where the first electrode 221 of at least one of the light-emitting devices 220 is connected to the auxiliary electrode 226 corresponding to the first electrode 221. This indicates that the bright spot(s), if present, of the display panel 200 has been repaired, the yield and the display quality of the display panel 200 are improved.

Specifically, as shown in FIG. 10, a reason for the occurrence of bright spots is illustrated by way of an example. During the manufacture process of the second metal layer 121, the power signal trace 123 is shorted to connect with the light shielding electrode 121 and the drain electrode 181 due to etching. Specifically, a residual metal 1214 is connected the light shielding electrode 121 with the power signal trace 123, so that the power signal trace 123 is directly electrically connected to the first electrode 221 of the light-emitting device 220 instead of connecting to the first electrode 221 by the driving transistor T1 of the pixel driving circuit. Thus, switching of the light-emitting device 220 is not controlled by the pixel driving circuit, and the light-emitting device 220 becomes a bright spot. By providing the auxiliary electrode 226 in the display panel 200 as described above, and repairing the display panel by the repairing method of the display panel as described above, the first electrode 221 of the light-emitting device connects to the auxiliary electrode 226 to change the bright spot into a dark pot.

Specifically, as shown in FIG. 7, a repair principle of the embodiment of the present application is described with reference to a circuit diagram. FIG. 7 illustrates that the first electrode is an anode, the second electrode is a cathode, and the auxiliary trace 31 is supplied with a potential of a cathode signal trace VSS, or the auxiliary trace 31 is connected to the cathode signal trace VSS.

Specifically, as shown in FIG. 7, each of the sub-pixels includes a pixel driving circuit, wherein the pixel driving circuit includes at least one driving transistor T1, at least one switching transistor T2, and at least one capacitor C. The pixel driving circuit drives the light-emitting device 220 to emit light, and the pixel driving circuit electrically connects a data signal trace Data, a scan signal trace Scan, a power signal trace VDD, and a cathode signal trace VSS. The power signal trace VDD is electrically connected to a source of the driving transistor T1, and the power signal trace V. DD is electrically connected to the first electrode of the light-emitting device 220 through the driving transistor T1. The cathode signal trace VSS is electrically connected to a cathode (the second electrode 223) of the light-emitting device 220, and the cathode signal trace VSS provides an electric single to an cathode of the light-emitting device 220.

Specifically, as shown in FIG. 10, after the display panel is repaired by the repairing method of the display panel as described above, the auxiliary electrode 226 and/or the first electrode 221 are melted to form the auxiliary connection electrode 2216, and the auxiliary connection electrode 2216 connects the auxiliary electrode 226 with the first electrode 221 corresponding to the auxiliary electrode 226, and thus, eliminating a large voltage difference between the first electrode 221 and the second electrode 223 to change a bright spot into a dark spot. Therefore, the abnormality due to the presence of bright spots in the display panel 200 can be improved or eliminated, and the yield and the display quality of the display panel can be improved.

It should be noted that the pixel driving circuit includes but is not limited to the configuration shown in FIG. 7. The pixel driving circuit may be a pixel driving circuit according to any in the prior art, and the detailed configuration of the pixel driving circuit is not described herein again.

The foregoing describes in detail a display panel and a repairing method of a display panel provided in the embodiments of the present application. The principles and embodiments of the present application are described by using specific examples. The description of the embodiments is merely intended to help understand the method and core ideas of the present application. At the same time, a person skilled in the art may make changes in the specific embodiments and application scope according to the idea of the present application. In conclusion, the content of the specification should not be construed as a limitation to the present application.

What is claimed is:

1. A display panel, comprising:
an array substrate, wherein the array substrate comprises a power signal trace and at least one auxiliary trace; and
a plurality of light-emitting devices disposed on the array substrate in an array, wherein each of the light-emitting devices comprises a first electrode and a second electrode, and the second electrode is disposed on a side of the first electrode away from the array substrate;
wherein the display panel further comprises a plurality of auxiliary electrodes disposed in the same layer as the first electrode, each of the auxiliary electrodes is disposed corresponding to the first electrode of at least one of the light-emitting devices, the auxiliary electrode is electrically connected to the auxiliary trace, and a potential of the auxiliary trace is less than a potential of the power signal trace.

2. The display panel according to claim 1, wherein a distance between the auxiliary electrode and the first electrode corresponding to the auxiliary electrode is less than or equal to 2 μm.

3. The display panel according to claim 1, wherein each of the auxiliary electrodes is disposed corresponding to the first electrodes of the plurality of light-emitting devices.

4. The display panel according to claim 3, wherein the plurality of light-emitting devices include red light-emitting devices, green light-emitting devices, and blue light-emitting devices, and each of the auxiliary electrodes is disposed corresponding to the first electrode of at least one of the red light-emitting devices, the first electrode of at least one of the green light-emitting devices, and the first electrode of at least one of the blue light-emitting devices.

5. The display panel according to claim 1, wherein the first electrode of at least one of the light-emitting devices is connected to the auxiliary electrode corresponding to first electrode.

6. The display panel according to claim 1, wherein the array substrate further comprises a thin film transistor, and a first metal layer disposed between the thin film transistor and the light-emitting device, wherein the auxiliary trace is disposed in a same layer as the first metal layer.

7. The display panel according to claim 2, wherein the array substrate further comprises a thin film transistor, and a first metal layer disposed between the thin film transistor and the light-emitting device, wherein the auxiliary trace is disposed in a same layer as the first metal layer.

8. The display panel according to claim 3, wherein the array substrate further comprises a thin film transistor, and a first metal layer disposed between the thin film transistor and the light-emitting device, wherein the auxiliary trace is disposed in a same layer as the first metal layer.

9. The display panel according to claim 5, the array substrate further comprises a thin film transistor, and a first metal layer disposed between the thin film transistor and the light-emitting device, wherein the auxiliary trace is disposed in a same layer as the first metal layer.

10. The display panel according to claim 6, wherein the first electrode is connected to a drain of the thin film transistor through the first metal layer.

11. The display panel according to claim 1, wherein the array substrate further comprises a thin film transistor, the thin film transistor comprises a gate electrode, an active layer, and a source/drain electrode, and the auxiliary trace is disposed in a same layer as the gate electrode or the source/drain electrode.

12. The display panel according to claim 2, wherein the array substrate further comprises a thin film transistor, the thin film transistor comprises a gate electrode, an active layer, and a source/drain electrode, and the auxiliary trace is disposed in a same layer as the gate electrode or the source/drain electrode.

13. The display panel according to claim 3, wherein the array substrate further comprises a thin film transistor, the thin film transistor comprises a gate electrode, an active layer, and a source/drain electrode, and the auxiliary trace is disposed in a same layer as the gate electrode or the source/drain electrode.

14. The display panel according to claim 5, wherein the array substrate further comprises a thin film transistor, the thin film transistor comprises a gate electrode, an active layer, and a source/drain electrode, and the auxiliary trace is disposed in a same layer as the gate electrode or the source/drain electrode.

15. The display panel according to claim 1, wherein the array substrate further comprises a second metal layer, and a thin film transistor disposed on the second metal layer, wherein the auxiliary trace is disposed in a same layer as the second metal layer.

16. The display panel according to claim 2, wherein the array substrate further comprises a second metal layer, and a thin film transistor disposed on the second metal layer, wherein the auxiliary trace is disposed in a same layer as the second metal layer.

17. The display panel according to claim 3, wherein the array substrate further comprises a second metal layer, and a thin film transistor disposed on the second metal layer, wherein the auxiliary trace is disposed in a same layer as the second metal layer.

18. A repairing method of a display panel, wherein in the display panel according to claim 1, the repairing method of the display panel comprises:
S100, irradiating the auxiliary electrode and the first electrode corresponding to the auxiliary electrode by a laser, to melt the auxiliary electrode and the first electrode to electrically connect to each other; and
S200, supplying a potential to the auxiliary trace, and supplying an electric signal by the auxiliary trace to the first electrode connected to the auxiliary electrode.

19. The method according to claim 18, wherein a distance between the auxiliary electrode and the first electrode corresponding to the auxiliary electrode is less than or equal to 2 μm.

20. The method according to claim 19, wherein each of the auxiliary electrodes is disposed corresponding to the first electrodes of the plurality of light-emitting devices.
